(19) United States
(12) Patent Application Publication
(10) Pub. No.: US 2009/0242868 A1
(43) Pub. Date: Oct. 1, 2009

(54) SEMICONDUCTOR DEVICE AND METHOD OF MANUFACTURING THE SAME

(75) Inventors: Kenzo KUROTSUCHI, Kodaira (JP); Motoyasu TERAO, Hinode (JP); Norikatsu TAKAURA, Tokyo (JP); Yoshihisa FUJISAKI, Hachioji (JP); Kazuo ONO, Kodaira (JP); Yoshitaka SASAGO, Tachikawa (JP)

Correspondence Address: MILES & STOCKBRIDGE PC, 1751 PINNACLE DRIVE, SUITE 500, MCLEAN, VA, 22102-3833, US

(73) Assignee: HITACHI, LTD.

(21) Appl. No.: 12/370,417

(22) Filed: Feb. 12, 2009

(30) Foreign Application Priority Data
Mar. 31, 2008 (JP) 2008-089776

(51) Int. Cl. H01L 45/00; H01L 21/28

(52) U.S. Cl. 257/4; 438/103; 257/42; 257/E45.002; 257/E21.158

(57) ABSTRACT

A solid electrolyte memory involves a problem that stable rewriting is difficult since the amount of ions in the solid electrolyte and the shape of the electrode are changed by repeating rewriting. In a semiconductor device in which information is stored or the circuit connection is changed by the change of resistance of the solid electrolyte layer, the solid electrolyte layer includes a composition, for example, of Cu—Ta—S and an ion supply layer in adjacent or close therewith as Cu—Ta—O, in which ions supplied from the ion supply layer form a conduction path in the solid electrolyte layer thereby making it possible to store information by the level of the resistance and applying the electric pulse to change the resistance, in which the ion supply layer includes crystals having, for example, a compositional ratio of: Cu—Ta—O=1:2:6 and rewriting operation can be performed stably.

### CLAIM OF PRIORITY

The present application claims priority from Japanese patent application JP 2008-089776 filed on Mar. 31, 2008, the content of which is hereby incorporated by reference into this application.

### BACKGROUND OF THE INVENTION

1. Field of the Invention

The present invention concerns a semiconductor device and a method of manufacturing the same and it particularly relates to a technique which is effective when applied to a memory cell using a solid electrolyte material for discriminating memory information by utilizing the difference of resistance, for example, a high density integrated memory circuit, a logic hybrid type memory in which a memory circuit and a logic circuit are disposed in one identical semiconductor substrate, or a semiconductor integrated circuit device having an analog circuit and, further, a random access memory at a high operation speed, having non-volatility, and operating at a low voltage.

2. Description of the Related Arts

As a recording technique using a solid electrolyte material, a solid electrolyte memory has been proposed. Details for the solid electrolyte memory are described in IEEE International Solid-State Circuits Conference (ISSCC) 2004, Digest, 2004, p. 16.3 and Proc. Non-Volatile Memory Technology Symposium (NVMTS) 2004, 2004, pp. 10-17. A structure for a memory area and a periphery thereof of a memory are to be described with reference to FIG. 2. A solid electrolyte memory has a structure of sandwiching a memory area RM between BEC and an upper electrode 15. The memory area RM has a stacked structure of a solid electrolyte layer 21 and an electrode 22 as an ion supply source. An ion of high mobility moves in the solid electrolyte 21. “Ion of high mobility” is defined as an ion moving for a long distance when a constant voltage is applied in a certain electrolyte. The material for the electrode 22 is an element A of high mobility (for example, Cu).

The material for the solid electrolyte 21 is an alloy having a composition of Cu and S, and the solid electrolyte 21 contains ions A. BEC is formed by stacking a plug material 13 of low ion conductivity and an adhesion layer 14. For the upper electrode 15, a metal material of low mobility is used. This prevents movement upon application of an electric field. In “ON state” where the resistance of the memory area RM is low, an electroconductive filament formed of a metal A in the solid electrolyte connects the electrode 22 and BEC.

On the other hand, in “OFF state” where the resistance of the memory area RM is high, the electroconductive filament is disconnected. The operation method is to be described. Upon reading a value, the resistance of the memory area RM is measured and a high or low level thereof is corresponded to “0” or “1” respectively. The “ON operation” for putting the memory area RM to “ON state” is performed as described below. When a positive voltage is applied to the electrode 22, the electrode 22 is oxidized into the ion A. Then, ions A are conducted tonically in the solid electrolyte, and reduced near the lower electrode BEC or the filament, by which the filament is formed or grown. When the filament connects the electrode 22 and BEC, the resistance of the memory area RM is lowered. “OFF operation” of putting the memory area RM to “OFF state” is performed as described below. When a negative voltage is applied to the electrode 22, the metal A constituting the filament are oxidized into ions A. Then, the ions A are diffused in the solid electrolyte.

A crystal structure including Cu, Ta, and O at a compositional ratio of: Cu—Ta—O=1:2:6 is reported in Journal of Applied Physics, Vol. 96, pp. 4400-4404). The crystal is defined as a Cu—Ta—O crystal.

U.S. Pat. No. 6,891,186 describes a semiconductor memory using an oxide material. Resistance is changed by forming or eliminating a metal filament. In the semiconductor memory of U.S. Pat. No. 6,891,186, the place in which the metal filament is formed and eliminated is not in the oxide material.

Further, JP-A No. 2006-351780 describes a semiconductor memory of a structure in which a laminate, for example, of CuTe (copper telluride compound and GdO_{X} (gadolinium oxide) is put between two electrodes and describes a method of improving the voltage withstanding of a memory layer by adding a metal element (for example, Cu) in the GdOₓ material.

### SUMMARY OF THE INVENTION

The solid electrolyte memory involves a problem that stable rewriting is difficult since the amount of the ions A in the solid electrolyte and the shape of the electrode are changed by repeating rewriting. A typical structure of a circuit device studied by us for solving the problem is to be described with reference to FIG. 3. While the supply layer for the ions A was the electrode 22 in the existent solid electrolyte memory, this is a solid electrolyte material in our memory. For example, this is Cu—Ta—S. Description is to be made to an example of Cu—Ta—S. Further, a filament forming area includes a ternary oxide. This is, for example, Cu—Ta—O. Description is to be made to an example of Cu—Ta—O. Further, the filament forming area is to be defined as an ion confinement layer. The effect obtained by the structure is to be described later. At first, by changing the ion supply source from the electrode 22 to the solid electrolyte Cu—Ta—S the total amount of ions that can be supplied is restricted, and further, a physical change such as formation of voids of the ion supply source is suppressed. Secondly, Cu and Ta of different mobilities are used as metal ions. Ta of low mobility forms a stable structure of TaS or TaO. On the other hand, Cu of high mobility changes the resistance of the memory area RM by forming and eliminating the electroconductive filament.

At first, the ON operation is to be described with reference to FIG. 3. When a voltage higher than that for a lower electrode 34 is applied to an upper electrode 31, Cu ions 33 having a positive charge in the Cu supply layer as the solid electrolyte are conducted tonically and moved to an ion confinement layer 11. For the sake of simplicity of explanation, it is assumed in the following description that a positive voltage is applied to the upper electrode and the lower electrode is kept at 0 V. In the ion confinement layer 11, Cu ions 33 are formed into metal Cu 34 by reducing reaction. The metal Cu 34 is formed particularly to a portion of the ion confinement layer 11 where current flows. Further, when the metal Cu 34 is formed, the resistance for the portion is lowered and the electric current is concentrated. Accordingly, the metal Cu 34 often has a filament shape. By the formation of the Cu filament, resistance of the memory area RM is lowered.

Then, an OFF operation is to be described with reference to FIG. 4. When a negative voltage is applied to an upper electrode 32 and a lower electrode 34 is kept at 0 V, metal Cu 34 in the Cu filament is oxidized into Cu ions. As a result, a portion of the Cu filament is eliminated to increase the resistance of the memory area RM. The Cu ions are moved by ionic conduction in the Cu supply layer 12.

The foregoing description is to be described again with reference to a current-voltage waveform shown in FIG. 5. The waveform was measured by using a semiconductor parameter analyzer. When an upper electrode voltage at about 0.3 V is applied, the ON operation 51 is generated to decrease the resistance. At the time of applying a voltage at about 0.5 V, the current shows a constant value of 300 μA, because it reaches a compliance current of a measuring equipment. Then, when a voltage at about −0.3 V is applied to the upper electrode, an OFF operation 52 is generated to increase the resistance. Each of the foregoing descriptions is valid also in a case where the polarity of the voltage upon operation is reversed. Further, this is also valid in a case where the relation between the ion confinement layer and the ion supply layer is turned upside down. As described above, this circuit device has now been put under study by us intending for high reliable operation.

However, an operation of further higher reliability is demanded in some application uses such as DRAM (Dynamic Access Memory) as application use of high reliability.

The technical problem intended to be solved by the invention is for the improvement of the technical problems described above and the invention intends to provide a highly reliable circuit device such as a memory device. Specifically, it intends to increase the number of endurance cycles and decrease variations in the rewriting voltage or rewriting resistance.

For attaining the foregoing object, the present invention intends to provide a semiconductor device in which the phase state of the ion confinement layer in the memory area RM is crystalline. Particularly, the ion confinement layer in the crystalline state has a composition including ions A of high mobility and ions C of lower mobility compared with that of the ions A and, further, ions D having a polarity opposite to that of the ions A and the ions C. An example of the composition for the ion confinement layer in the crystalline state is: Cu—Ta—O=1:2:6. Since the crystallized ion confinement layer is stable, physical deformation of the memory area RM and excess fluctuation of the compositional ratio in the memory area RM. are less caused in a case of performing the rewriting operation. Accordingly, stable rewriting operation is possible.

Among the inventions disclosed in the present application, effects obtained by typical inventions are to be described below simply.

A memory device of high endurance characteristics can be attained.

### BRIEF DESCRIPTION OF THE DRAWINGS

FIG. 1 is a cross sectional view for a main portion of a memory device in one embodiment of the invention;

FIG. 2 is a cross sectional view for a main portion of a solid electrolyte memory device;

FIG. 3 is a model view showing an ON operation in one embodiment of the invention;

FIG. 4 is a model view showing an OFF operation in one embodiment of the invention;

FIG. 5 is a graph showing a relation between current and voltage;

FIG. 6 is a view showing the structure of a CuTa₂O₆ crystal;

FIG. 7 is a graph showing a relation between a number of cycles and a reading current in a case where an ion confinement layer is in the crystalline state;

FIG. 8 is a graph showing a relation between a number of cycles and a reading current in a case where an ion confinement layer is in the amorphous state;

FIG. 9 is a cross sectioned SEM photograph for the periphery of crystalline Cu—Ta—O;

FIG. 10 is a schematic cross sectional view for the periphery of crystalline Cu—Ta—O;

FIG. 11 is a graph showing the result of XRD measurement for Cu—Ta—O;

FIG. 12 is a cross sectional view schematically showing a constituent example for a main portion of a semiconductor device in Embodiment 1 of the invention during a manufacturing step thereof;

FIG. 13 is a view showing three types of crystallizing methods for an ion confinement layer;

FIG. 14 is a cross sectional view schematically showing a semiconductor device during a manufacturing step succeeding to FIG. 12;

FIG. 15 is a cross sectional view schematically showing a semiconductor device during a manufacturing step succeeding to FIG. 14;

FIG. 16 is a cross sectional view schematically showing a semiconductor device during a manufacturing step succeeding to FIG. 15;

FIG. 17 is a view schematically showing a layout for a main portion of a semiconductor device according to Embodiment 1 of the invention during a manufacturing step thereof;

FIG. 18 is a view schematically showing a layout for a main portion of a semiconductor device according to Embodiment 1 of the invention during a manufacturing step thereof;

FIG. 19 is a view schematically showing a layout for a main portion of a semiconductor device according to Embodiment 1 of the invention during a manufacturing step thereof;

FIG. 20 is a cross sectional view schematically showing a main portion of a semiconductor device according to Embodiment 1 of the invention during a manufacturing step thereof;

FIG. 21 is a cross sectional view schematically showing a main portion of a semiconductor device according to Embodiment 1 of the invention during a manufacturing step thereof;

FIG. 22 is a cross sectional view schematically showing a main portion of a semiconductor device according to Embodiment 4 of the invention during a manufacturing step thereof;

FIG. 23 is a cross sectional view schematically showing a semiconductor device during a manufacturing step succeeding to FIG. 22;

FIG. 24 is a cross sectional view schematically showing a semiconductor device during a manufacturing step succeeding to FIG. 23;

FIG. 25 is a diffraction pattern for a CuTa₂O₆ crystal obtained by analyzing a memory cell by electron beam diffraction; and

FIG. 26 is an electron beam diffraction pattern for the CuTa₂O₆ crystal obtained by calculation.

### DETAILED DESCRIPTION OF THE PREFERRED EMBODIMENTS

Preferred embodiments of the present invention are to be described specifically with reference to the drawings. In the invention, contact between conductor layers includes not only a case of direct contact but also a case where they are in contact with each other while sandwiching a thin layer or a region of an insulator or a semiconductor that allows a current to flow therethrough.

### Embodiment 1

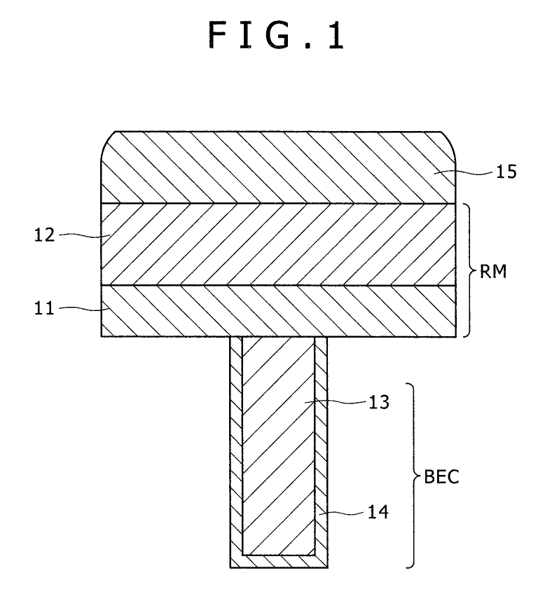

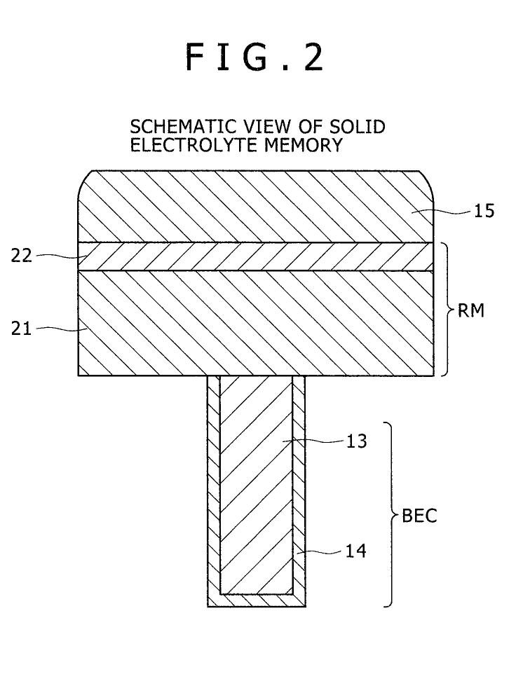

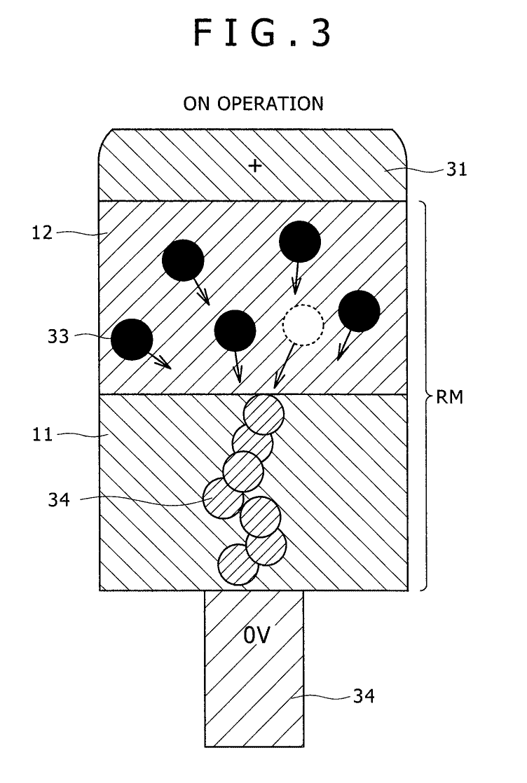

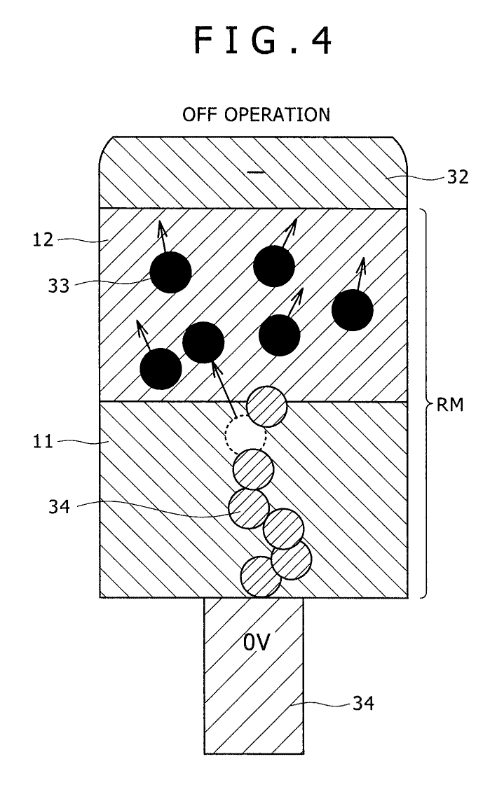

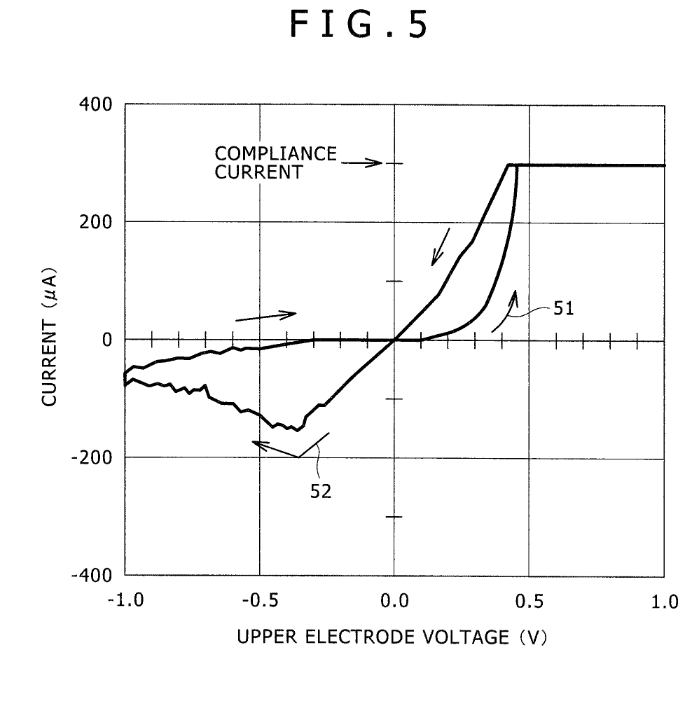

FIG. 1 is a cross sectional view showing the constitution of a memory device using a solid electrolyte material according to the first embodiment of the invention. As shown in the drawing, the memory device of the invention has a structure in which a memory area RM where an ion confinement layer 11 and an ion supply layer 12 are stacked is sandwiched between a lower electrode BEC and an upper electrode 15. The lower electrode BEC includes an adhesion layer 14 and a plug material 13. For the adhesion layer 14, TiN of excellent burying property to a hole shape of fine dimension can be used for example. As the material for the plug material 13 and the upper electrode 15, W of low electric resistance can be used. As the material for BEC, TiAlN or TiW, TiSiC, TaN, carbon cluster (carbon allotrope such as C60) as high melting materials can be used. In this case, as a method of eliminating an electroconductive filament, a method of generating Joule heat to the ion confinement layer and eliminating the filament by thermal diffusion can be used. As a result, a voltage of an identical polarity can be used for the ON operation and the OFF operation, and the area for the peripheral circuit can be reduced.

As the material for the plug material 13, the adhesion layer 14, and the upper electrode 15, elements of low mobility are used preferably so as not to give undesired effects on the rewriting operation. Naturally, an identical material, for example, TiN can be used for the plug material 13 and the adhesion layer 14. The phase state of the ion confinement layer 11 is crystalline, and a composition including Cu, and Ta, O can be used as the material. The ion confinement layer 11 includes positive ions and negative ions. The positive ions include two or more kinds of positive ions and negative ions having difference in the mobility. Positive ions of high mobility are ions of small valence number and having a small ionic radius. Ag, Cu, Au, or Zn corresponds thereto. Further, positive ions of low mobility are ions of large valence number and having a large ionic radius, and Ta, W, Mo, or rare earth element (particularly, Gd) corresponds thereto. As the material for the ion supply layer 12, a composition including Cu, Ta, and S can be used. The ion supply layer includes positive ions and negative ions. Further, by using two or more kinds of positive ions of different mobilities for the positive ions, physical change such as voids or excessive resistance change can be prevented from being formed to the ion supply layer by a stable structure formed by the positive ions of low mobility and negative ions.

Further, when negative ions of the ion confinement layer 11 are elements different from the negative ions of the ion supply layer 12, it is possible to make a difference to the ion conductivity between the ion confinement layer 11 and the ion supply layer 12 and keep the gradient of the ionic concentration in one direction. The ionic concentration is higher near the upper electrode 15 and lower near the lower electrode BEC. In a case where the gradient of the ionic concentration is reversed, since the polarity of the rewriting voltage is reversed, no stable rewriting operation can be performed. This embodiment intends to keep the gradient of the ion concentration by making a difference in the ionic conductivity.

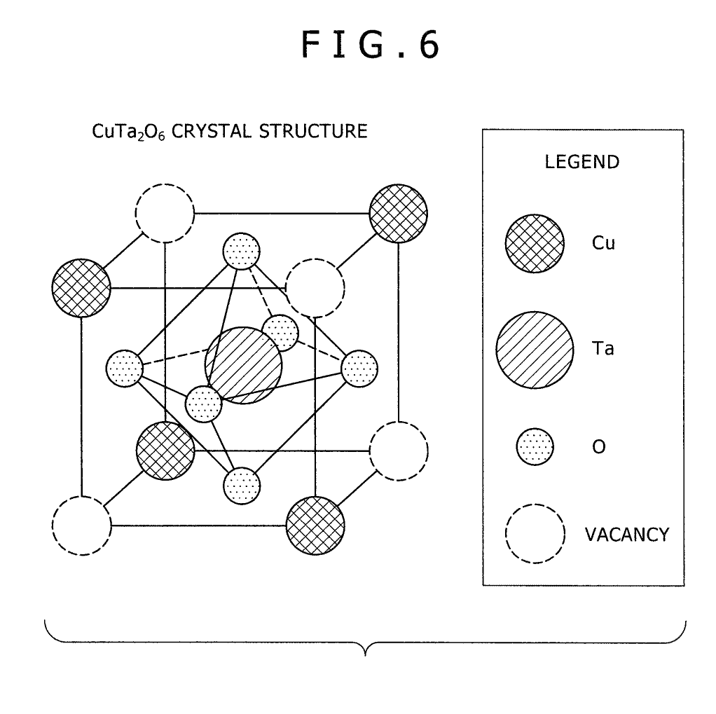

The invention has a feature of making the phase state of the ion confinement layer 11 crystalline. Description is to be made with reference to FIG. 6 to a crystal structure in a case of using Cu, and Ta, O at a compositional ratio thereof being approximate to: Cu—Ta—O=1:2:6 as the composition of the ion confinement layer. The crystal structure is a somewhat distorted perovskite structure. Oxygen situates at each apex of an octahedron and Ta situates at the center. When taking notice on a Cu site shown by a Cu atom and a vacancy in FIG. 6, vacancies are present for 1/2 of the Cu sites. There is also a report that the ratio of the vacancies in the Cu sites is 1/3. Further, there is also a report that the compositional ratio is: Cu—Ta—O=1.03:2:6. Since a number of vacancies contained in the Cu sites form a path when Cu ions are moved, they have high ionic conductivity. On the other hand, it is considered that the structure constituted by Ta and O is stable and the structure is not deteriorated easily and less causes formation of voids or movement of Ta or O even in a case where an electric field is applied or Cu ions are moved. This is because positive ions of low mobility generally have large valence number and accordingly, a firm bonding is formed between them and oxygen as the negative ion. Accordingly, a memory device having high reliability can be provided.

For a preferred composition of the ion supply layer, an average composition is represented by the following general formula (1).

Cu_{X}Ta_{Y}S_{(100-X-Y)} (1)

(in which X and Y in the formula are represented each as: 40≦X≦80, 5≦Y≦20).

When the compositional ratio for Cu is more than the ratio described above, the resistance of the layer itself is lowered just like the electrode and does not function as the solid electrolyte. When the ratio is lower than that described above, the film becomes chemically instable, and setting becomes insufficient. When the compositional ratio of Ta is more than that described above, the set resistance is excessively high. When the ratio is lower than that described above, since voids are formed upon movement of the ions, possible number of rewriting cycles is decreased. In addition to them, other element may also be contained by 10 at % or less.

For a preferred composition of the ion confinement layer, the average composition is represented by the following general formula (2).

Cu_{X}Ta_{Y}O_{(100-X-Y)} (2)

(in which X and Y in the formula are represented each as: 10≦X≦50, 10≦Y≦30).

When the compositional ratio for Cu is more than that described above, the resistance of the layer itself is lowered just like the electrode and does not function as the solid electrolyte. When the ratio is lower than that described above, the film becomes chemically instable, and setting becomes insufficient. When the compositional ratio for Ta is more than that described above, the set resistance is excessively high. When the ratio is lower than that described above, heat resistance in the state of low resistance is insufficient. When the ratio for oxygen is more than that described above, setting becomes insufficient. When it is less than that described above, since voids are formed upon movement of the ions, possible number of rewritable cycles is decreased. In addition, other elements may also be contained by 10 at % or less.

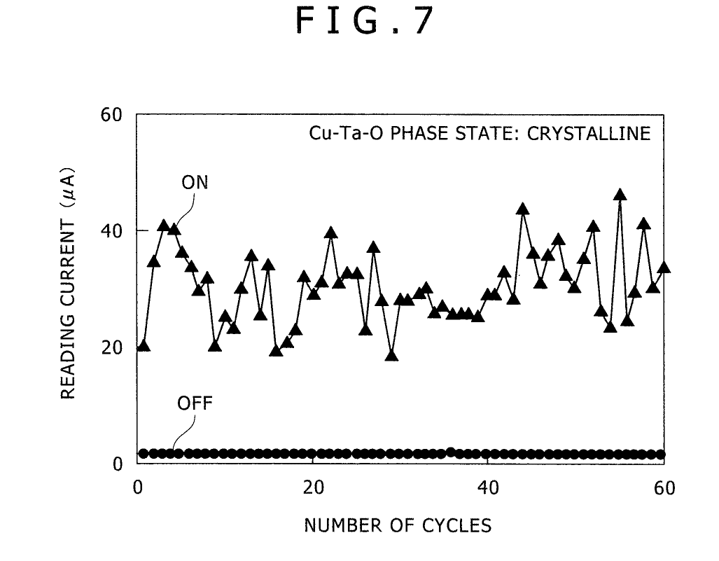

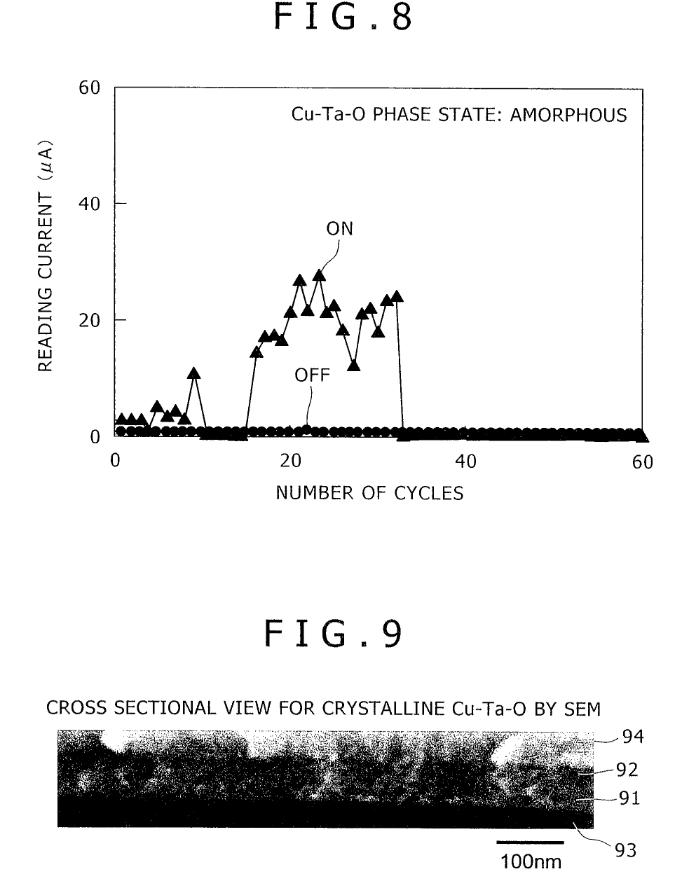

FIG. 7 and FIG. 8 show the phase state of the confinement layer of our experiment in comparison between an amorphous state and a crystalline state. FIG. 7 shows the crystalline phase state and FIG. 8 shows the amorphous phase state. They show the amount of current flowing upon reading operation. It shows that the stability of the reading current is improved when the rewriting operation is repeated by making the phase state crystalline. According to this, it can be seen that a memory operating at high reliability can be provided by crystalline Cu—Ta—O. One of models for explaining the reason is as described below. In a case where Cu—Ta—O is amorphous, bonding force between ions is different depending on the sites. Instable bonds are present in them and the bond between Ta and O is disconnected by the application of the electric field or movement of Cu ions. When the disconnected bonding between Ta—O bonds reaches a predetermined ratio, voids are formed by electromitigation. As a result, ON resistance, OFF resistance, and operation voltage fluctuate. When Cu—Ta—O is crystallize, a model in which Cu ions are moved mainly along the Cu sites in Cu—Ta—O and a model in which they are moved mainly for along grain boundary. In the model where the ions are moved mainly for the Cu sites in Cu—Ta—O, the bonding force between ions is substantially constant at least within the grain and a site where the bonding strength is weak and a void may be formed is not generated. Accordingly, it may be considered a possibility that stable rewriting operation is possible. In the model in which Cu ions are moved along the grain boundary, since the sites for the grain boundary is substantially stable, it may be considered a possibility that stable rewriting operation is possible.

Then, FIG. 9 shows a cross sectioned SEM image for crystalline Cu—Ta—O and a peripheral portion thereof prepared by us. It can be seen from SEM observation that a structure of about 5 nm is present in crystalline Cu—Ta—O 91. This suggests that the grain size of the Cu—Ta—O crystal 91 is about 5 nm. Further, FIG. 9 shows Cu—Ta—S 92, an upper electrode 94, and PTEOS 93.

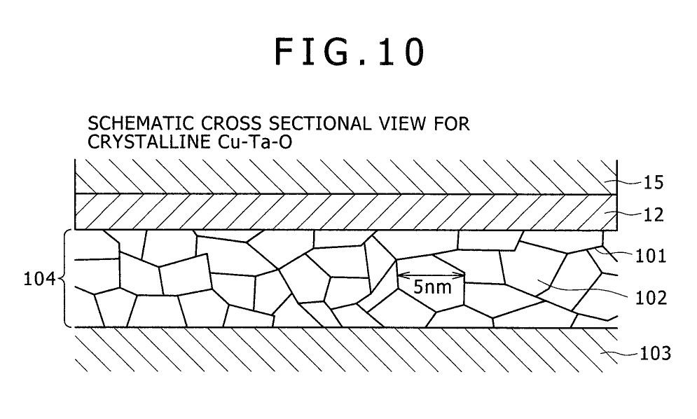

A schematic view of FIG. 9 is shown in FIG. 10. Crystalline Cu—Ta—O 104 is present between silicon oxide 103 and an ion supply layer, that is, Cu—Ta—S. It is shown that the crystal grain size of Cu—Ta—O is about 5 nm by the shape of the crystal grain boundary 101.

Electro conductivity and Cu mobility are different between the inside of grain 102 and at the grain boundary 101. By making the grain size sufficiently smaller compared with the diameter of the lower electrode BEC, effect of the Cu—Ta—O grain boundary on the memory property is averaged to provide an effect of decreasing the inter-device fluctuation. It is obvious that Cu, Ta and oxides thereof can be deposited to the crystal grain boundary 101 by composition or crystallizing condition of Cu—Ta—O. It is considered that determination is possible as to whether the movement of Cu is caused mainly in the grain or caused at the grain boundary depending on the amount of deposition and the composition thereof. A memory of large capacity can be provided by decreasing variations between the devices. Further, by improving the reliability of operation, application to RAM requiring large possible number of rewriting is possible. Particularly, the memory device of the invention can be provided as a main memory device corresponding to refinement of 45 nm or less by replacing DRAM having an extensive market as the main memory device for computers but involves a problem in the refinement 45 nm or less for the process generation.

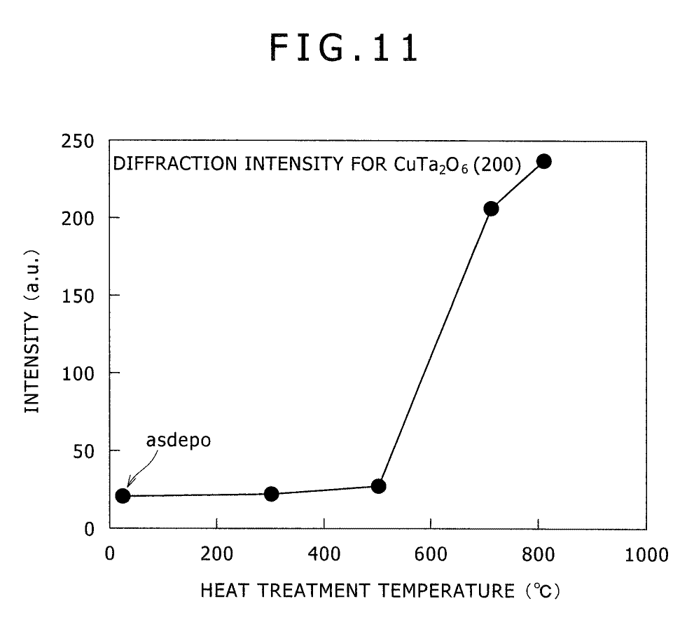

Conditions for crystallization of Cu—Ta—O are to be described with reference to FIG. 11. At first, an amorphous Cu—Ta—O film was formed by a sputtering method. Then, a heat treatment was applied for 30 min in a nitrogen atmosphere at respective predetermined temperatures. As a result of XRD measurement for the specimen, Cu—Ta—O crystals were not observed for an as-deposited film and at a heat treatment temperature of 500° C. or lower. On the contrary, Cu—Ta—O crystals were observed by performing the heat treatment at 700° C.

Further, we have further made an experiment for investigating the electric resistance of Cu—Ta—O, and it has been found that crystallizing temperature of Cu—Ta—O used in our experiment is 500° C. or higher and 700° C. or lower. The film thickness of Cu—Ta—O is, for example, from 5 to 60 nm and the film thickness of Cu—Ta—S is, for example, from 3 to 30 nm.

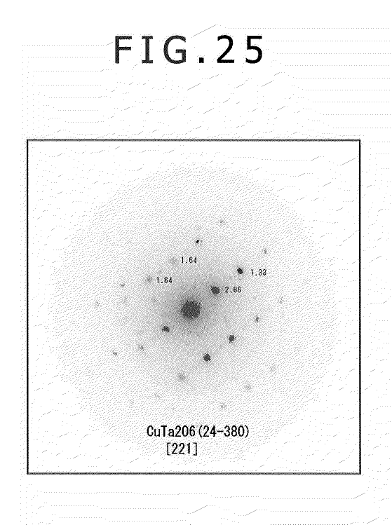

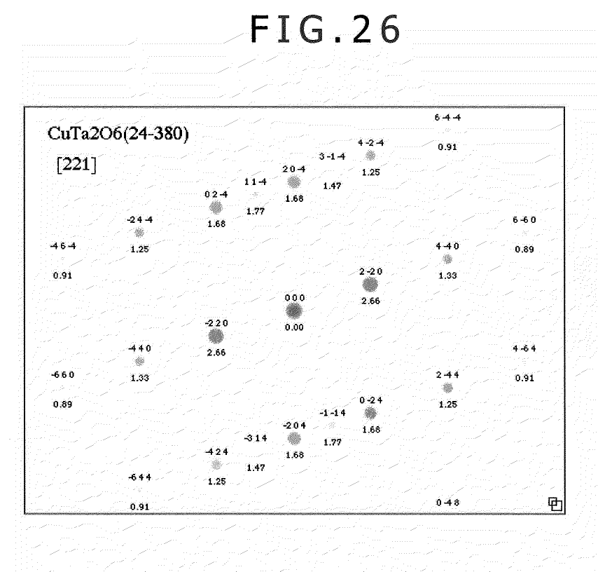

We observed a cross sectioned TEM (Transmission Electron Microscope) observation for the trially manufactured memory cell and FIG. 25 shows an electron beam diffraction pattern obtained by a nano-diffraction method. Further, FIG. 26 shows the result of calculation for the diffraction pattern based on the structure of Cu—Ta 206 crystal. Since the result agrees between FIG. 25 and FIG. 26, it can be seen that Cu—Ta 206 crystals are present in the memory cell. As described above, it can be examined easily whether the ion confinement layer is crystallized or not by the cross sectioned TEM observation.

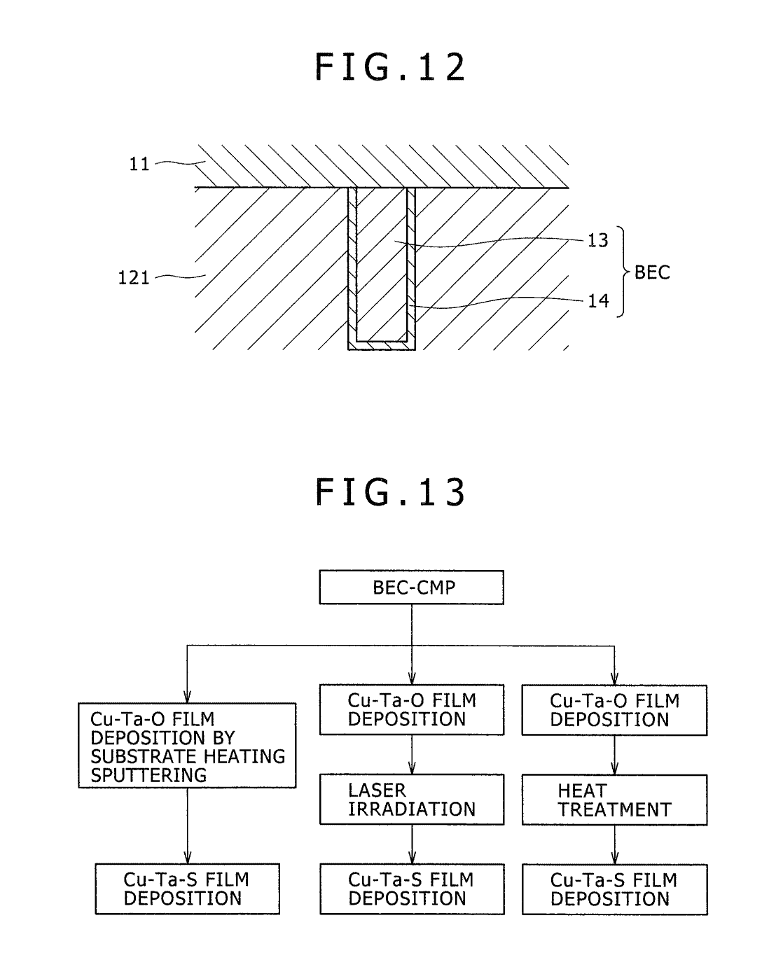

A vertical relation between Cu—Ta—O and Cu—Ta—S is to be described below. In a case of using a process step of forming a Cu—Ta—O film, crystallizing Cu—Ta—O and then forming a Cu—Ta—S film, since the heat resistant temperature of Cu—Ta—S may be lower than the crystallizing temperature of Cu—Ta—O, materials for Cu—Ta—S can be selected from wide compositions. For example, a composition of Cu:Ta:S=60:10:30 that sublimates by applying a thermal load at 600° C. can be used. Referring to the compositional ratio for Cu—Ta—S, when the Cu concentration is 10% or more and 50% or less, and Ta concentration is 10% or more and 30% or less, for instance, the amount of Cu supply is sufficient for the change of the resistance and this is considered to be advantageous for suppressing voids of the Cu—Ta—S material when Cu is supplied but use of other compositions is of course possible. Then, a manufacturing step of this memory is to be described with reference to FIG. 12.

At first, by using a usual semiconductor step, an MIS transistor is formed and a diffusion layer is separated by a field oxide film. Then, after forming an interlayer dielectric film, a contact hole connected with the drain of the transistor is formed, and an adhesion layer 14 and a plug material 13 are formed by a chemical vapor deposition method. Then, CMP (Chemical Mechanical Polishing) is performed to form BEC. Further, a crystalline Cu—Ta—O film is formed. FIG. 12 shows a schematic view of a structure obtained as a result. Only the region for BEC and its upper portion are shown. As the interlayer dielectric film 121, PTEOS (plasma tetra ethyl ortho silicate)can be used.

FIG. 13 shows three types of film forming method for crystalline Cu—Ta—O. In this embodiment, Cu—Ta—O film formation by a sputtering method for the substrate heating was selected. In the method, sputtering is performed while controlling the wafer substrate temperature, for example, to 500° C. or higher. It is of course possible to use other materials than Cu—Ta—O crystals for the ion confinement layer and, since the crystallizing temperature is different depending on the composition, it is necessary to select an appropriate substrate temperature in accordance with the composition.

Since sputtered particles incident by the sputtering to the substrate have high kinetic energy and can move freely to some extent on the substrate, they tend to form a crystalline state which is thermodynamically stable. Accordingly, temperature required for crystallization can be lowered compared with a case of forming a film in an amorphous state and then applying a thermal load. As a result, since the dopant injected into the silicon substrate moves by a high thermal load, this can avoid a problem that transistor characteristics are deteriorated.

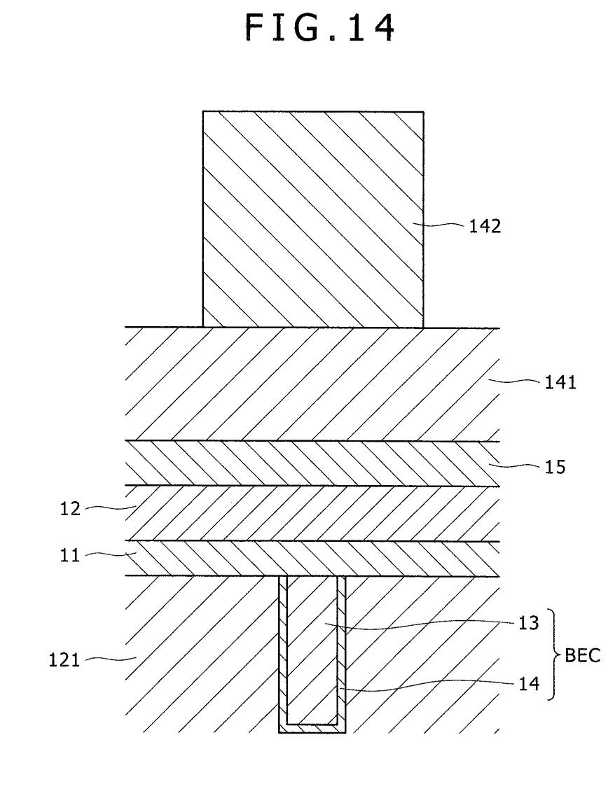

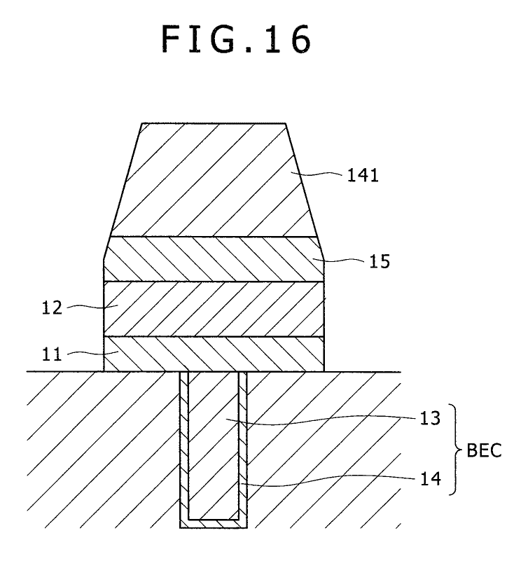

Then, a fabrication method for Cu—Ta—O and Cu—Ta—S is to be described. For Cu-containing materials, fine fabrication by etching is generally difficult. For example, a damascene step is used in the Cu wiring step. A fabrication method in this embodiment is to be described with reference to FIG. 14 to FIG. 16.

FIG. 14 shows a schematic view in a case of further forming films for Cu—Ta—S, an upper electrode 15, and a hard mask 141 from the state shown in FIG. 12, and then coating the resist 142 and applying exposure and development. As the hard mask 141, SiN (silicon nitride) can be used. The film thickness of the hard mask 141 is, for example, 150 nm. For the film thickness, an appropriate value is selected in accordance with the process generation of manufacturing apparatus and film thickness of Cu—Ta—S and Cu—Ta—O.

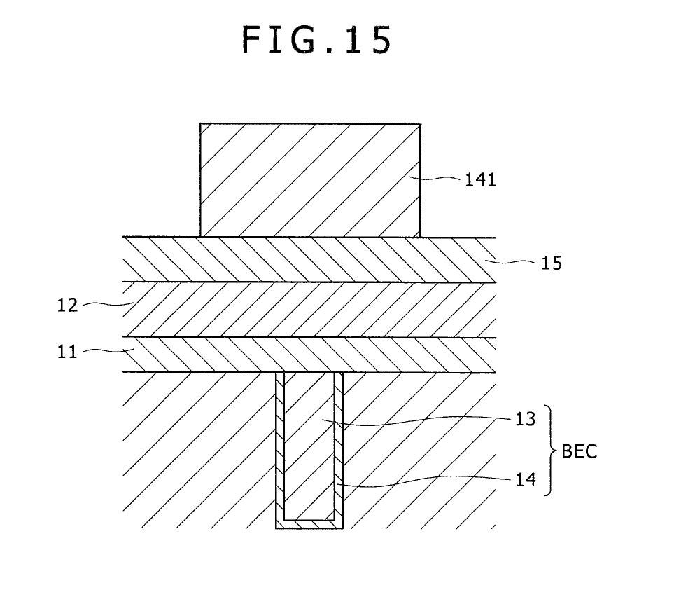

The hard mask 141 is fabricated by dry etching using a resist 142 as a mask. Then, resist ashing is performed to remove the resist 142. FIG. 15 shows a schematic view in this state.

Further, Cu—Ta—S and Cu—Ta—O are fabricated by dry etching using the hard mask 141. Since a higher selective ratio can be taken for the hard mask 141 to the Cu—Ta—O and Cu—Ta—S compared with the resist 142, finer fabrication is possible.

Then, connection portion between the memory area RM and a bit line and a connection portion between the source of the MIS transistor and a source line are formed and upper wirings are formed successively.

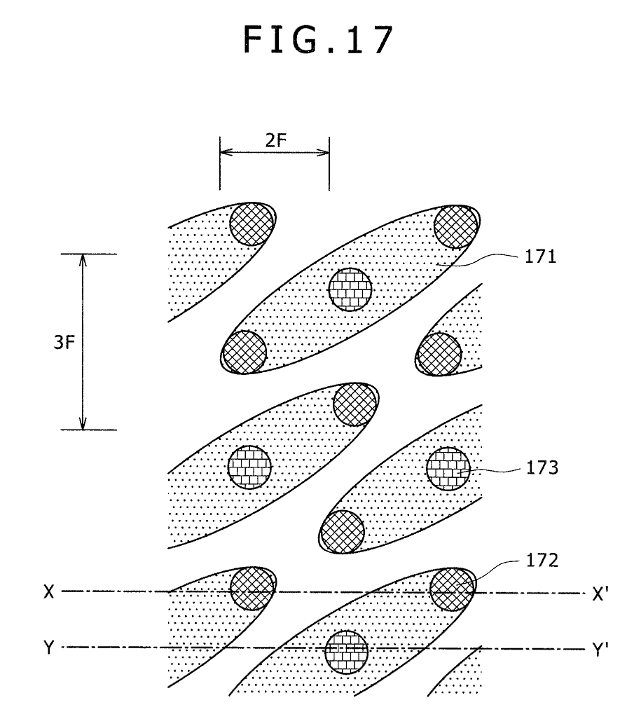

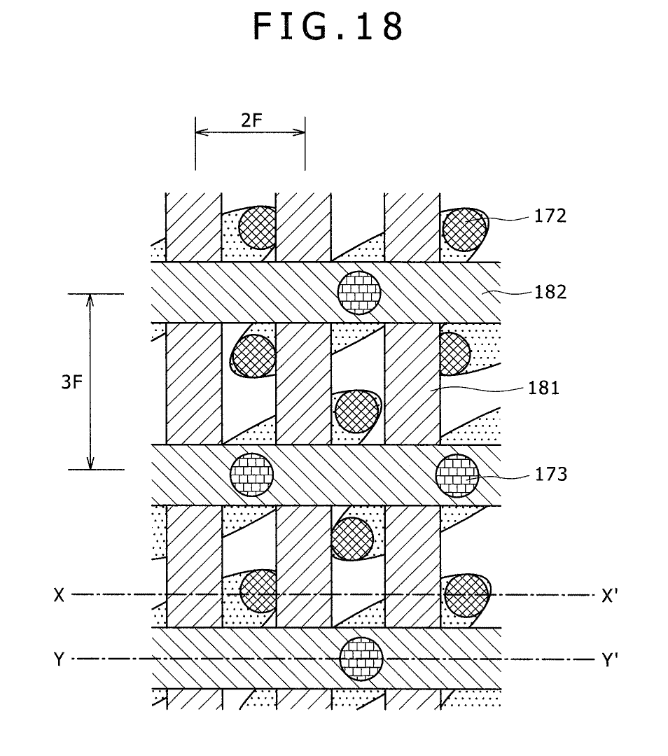

FIG. 17 to FIG. 19 show layouts for memory cells formed by the procedures described above.

FIG. 17 shows a diffusion layer 171, BEC 172, and connection portion 173 between the source line and the diffusion layer.

Then, FIG. 18 shows a word line 181 and a source line 182. An inter-source line distance is 3F assuming F as a minimum size. Further, an inter-word line distance is 2F.

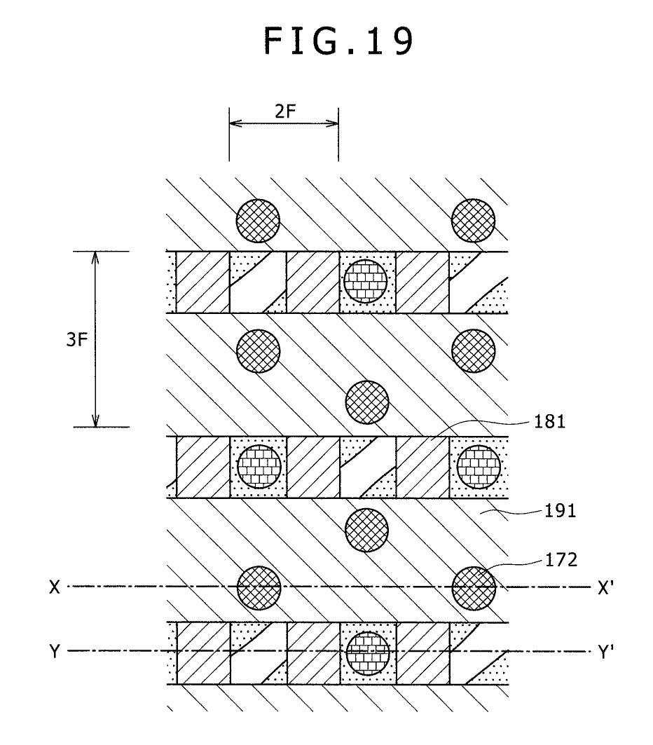

Further, FIG. 19 shows a bit line 191. The bit line distance is 3F. In this embodiment, the memory cell area can be 6 F². The plug diameter for the lower electrode BEC is, for example, from 0.2 F² to 2 F². In a case of fabricating the plug diameter of the lower electrode BEC to 1 F² or less, a method of fabrication, for example, by utilizing the step difference, for example, on the side wall as a hard mask, etc. can be used.

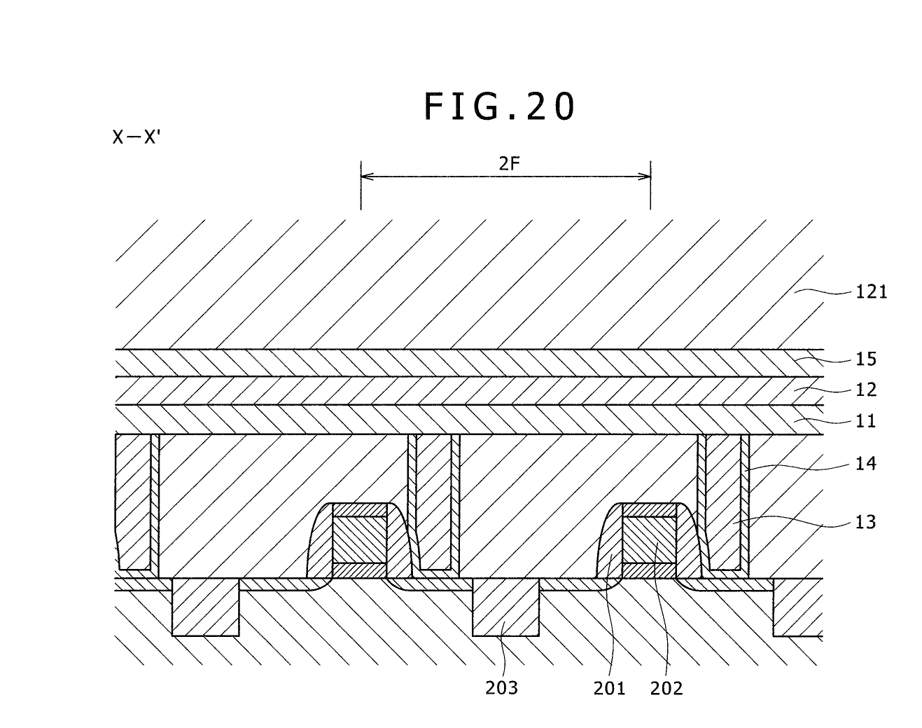

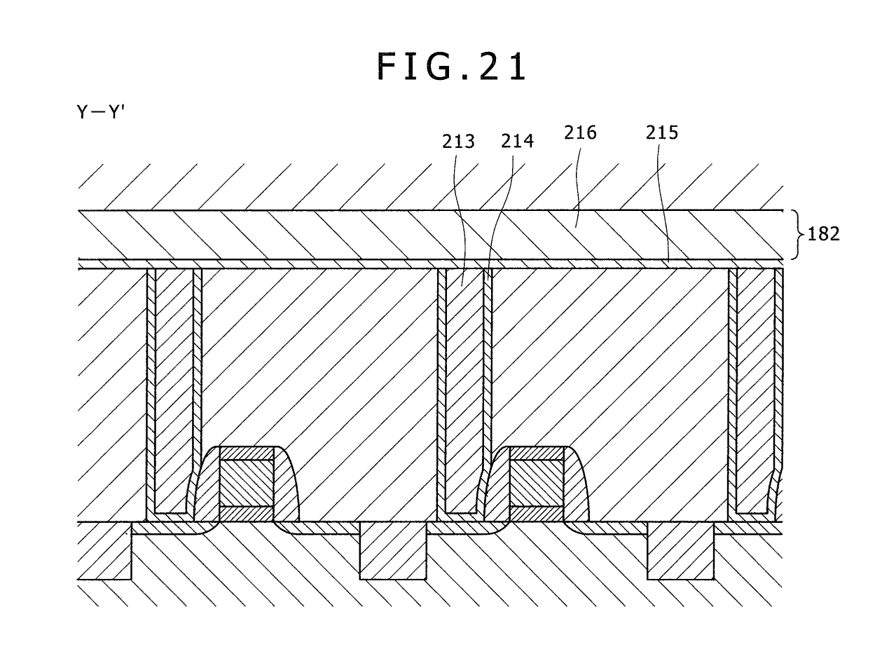

FIG. 20 and FIG. 21 show schematic cross sectional views for a main portion of this embodiment. FIG. 20 is a schematic cross sectional view along line X-X′ in FIG. 19 and FIG. 21 is a schematic cross sectional view along Y-Y′ in FIG. 19. FIG. 20 shows separation between the word line 202 and BEC by utilizing the side wall 201. The diffusion layer 171 is separated by the field oxide film 203.

FIG. 21 shows that a diffusion layer-source line connection portion 173 formed of an adhesion layer 214 and a plug material 213 connects the source line 182 and the diffusion layer 171. The adhesion layer 214 is, for example, made of TiN and the plug material 213 is, for example, made of W. Both of them can be formed by CVD. The source line 182 is formed of the barrier layer 215 and the wiring material 216. Ta can be used as the barrier layer and Cu can be used as the wiring material.

### Embodiment 2

This embodiment has a feature that the ion confinement layer is crystallized by laser irradiation in the Cu—Ta—O crystallization methods shown in FIG. 13.

Film formation of Cu—Ta—O is performed as described below. An amorphous Cu—Ta—O film is formed while controlling the substrate temperature upon sputtering to such a low level that Cu—Ta—O is not crystallized. Then, crystallization is performed for Cu—Ta—O by using laser irradiation.

Elevation for the temperature of the silicon wafer substrate can be mitigated by using laser irradiation not by a heat treatment using a furnace. Thus, since not only the problem that the transistor characteristics are deteriorated due to movement of a dopant in the diffusion layer can be avoided but also degradation of Low-k material can further be prevented, a Low-k material can be used for the interlayer dielectric film. By using the Low-k material, wiring delay in the semiconductor circuit can be mitigated and high speed operation can be performed. Generally, a Low-k material has low heat resistance. For example, when a thermal load exceeding 400° C. is applied to a porous Low-k material, since fine voids in the inside are eliminated to increase the dielectric constant k, wiring delay increases or wiring short circuit is caused by the deformation of Low-k material. The temperature at which a Low-k material is deteriorated naturally varies depending on the type of Low-k materials.

A laser irradiation method is to be described. A wafer is rotated around an axis in perpendicular to the surface of a silicon wafer and passing through the wafer center as a center, and a laser irradiation area is moved in the radial direction of the wafer. Further, the rotational speed is changed by the position of the laser irradiation region thereby keeping the linear speed of the laser constant. With the foregoing, a laser heat treatment at a uniform irradiation strength is possible.

The diffraction index of Cu—Ta—O in an amorphous state according to our measurement was 3.9 at a wavelength of 632.8 nm. While it is considered that crystallization is possible by controlling the laser irradiation intensity to 16 kW/mm², the moving speed of the laser irradiation region to 25 mm/sec, and the irradiation length in the moving direction of the laser to 1 μm, since the diffraction index, the crystallization temperature, and the time required for crystallization vary depending on the composition of the Cu—Ta—O material, the irradiation intensity and the moving speed of the irradiation region are naturally controlled to optimum values.

Further, it is possible to crystallize Cu—Ta—O by selective heating by the laser irradiation and suppress temperature elevation for Cu—Ta—S formed therebelow. As a result, a structure where Cu—Ta—S is present below Ca—Ta—O can be formed by using Cu—Ta—S of a lower heat resistance temperature than the crystallization temperature for Cu—Ta—O.

### Embodiment 3

This embodiment has a feature in crystallizing Cu—Ta—O by applying heat treatment in an electric furnace or IR furnace after forming an amorphous Cu—Ta—O film among the crystallization methods for Cu—Ta—O in FIG. 13. A fine crystal structure can be obtained by performing crystallization while taking a long time since this can suppress the crystal growing rate and, relatively, increase the probability of formation of crystal nuclei. Since this can make the number of grain boundaries on BEC uniform, effects of grain boundaries on the rewriting operation can be averaged. As a result, a semiconductor circuit device of less variation can be provided. The heat treatment time is, for example, 30 min. As described in Embodiment 1, since the crystallization temperature for Cu—Ta—O is 600° C. or higher, the heat treatment temperature is preferably 600° C. or higher.

### Embodiment 4

This embodiment has a feature of separating the memory area by CMP.

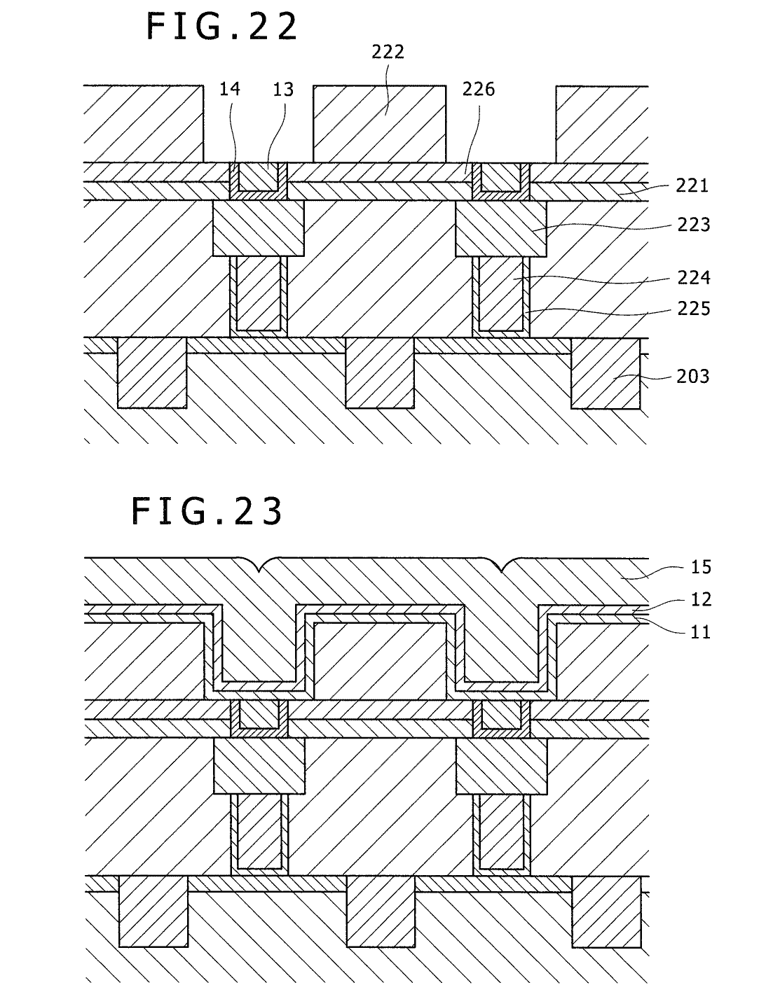

The manufacturing step of this memory is to be described with reference to FIG. 22 to FIG. 24.

At first, MIS transistor is formed and a diffusion layer is separated by a field oxide film by using a usual semiconductor step. Then, after forming an interlayer dielectric film, contact holes connected with the drain and the source of the transistor are formed, and an adhesion layer 225 and a plug material 224 are formed by a chemical vapor deposition method (CVD). Then, CMP (Chemical Mechanical Polishing) is applied to form a connection portion between diffusion layer and 1 metal wire. Then, 1 metal wire 223 is formed by using a CVD film deposition and damascene fabrication. An example of the 1 metal wire material is W. Then, an etching stopper layer 221 and an interlayer dielectric film 226 are formed and, further, CVD and dry etching are performed to form a step difference portion 222. An example of the material for the etching stopper layer is SiN and an example of the material for the interlayer dielectric film 226 is PTEOS. Further, an example of the material for the step difference portion 222 is SiN. FIG. 22 shows a schematic view for the cross section obtained as a result.

Further, the ion confinement layer 11, an ion supply layer 12, and an upper electrode 15 are deposited. All of such film deposition can be performed by a sputtering method. However, in a case of using a deep hole with an aspect ratio between the height and the opening of the step difference portion exceeding 1, each of the layers is formed by using a CVD method. FIG. 23 shows a schematic view for a cross section obtained as a result.

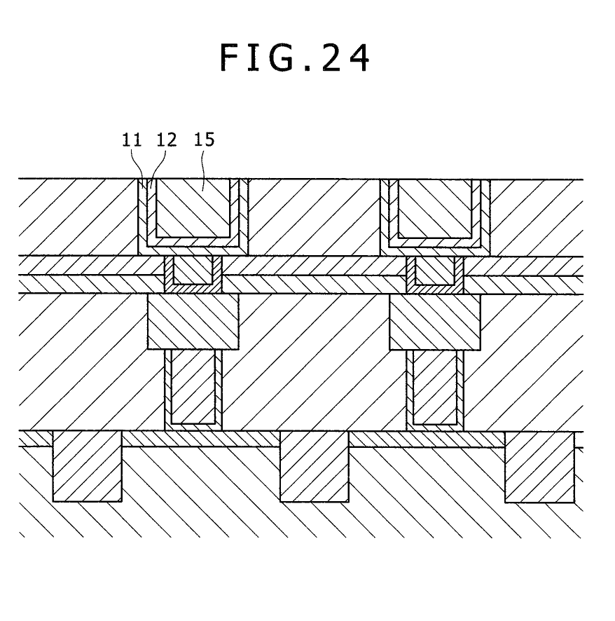

Then, by performing CMP, a structure in which the memory area is separated shown in FIG. 24 can be formed. By using this embodiment, a particularly fine memory cell structure can be formed.

Subsequently, by forming the upper wiring, a memory device is manufactured. Further, in a case of forming this structure by using a general semiconductor process, a step difference of from 10 to 500 nm is formed for Cu—Ta—O or Cu—Ta—S.

In this embodiment, the source line is disposed below the bit line, and the source line is wired by using the 1 metal wire 223. Further, a dry etching stopper layer 221 is formed so that the connection portion between the 1 metal wire and the upper wiring can be formed easily.

What is claimed is:

1. A semiconductor device comprising:
a recording layer disposed above a substrate for recording information by causing change of electric resistance;
a first electrode disposed on one main surface of the recording layer on the side of the substrate; and
a second electrode disposed on the other main surface of the recording layer opposing to said one main surface,
wherein the recording layer includes at least two layers of a first layer disposed on the side in contact with the first electrode and a second layer disposed on the side in contact with the second electrode,
wherein the first layer is a crystalline phase including at least one element selected from the group consisting of Ag, Cu, Au, and Zn, and at least one element selected from the group consisting of Ta, W, Mo, and Gd, and oxygen, and
wherein the second layer contains at least one element selected from the group consisting of Ag, Cu, Au, Zn and at least one element selected from the group consisting of S, Se, and Te.

2. The semiconductor device according to claim 1, wherein the elements selected from the group consisting of Ag, Cu, Au, and Zn contained in the first layer and the second layer are elements in common to each of the layers.

3. The semiconductor device according to claim 1, wherein the second layer contains at least one element selected from the group consisting of Ag, Cu, Au, and Zn, at least one element selected from the group consisting of S, Se, and Te, and a metal element or silicon.

4. The semiconductor device according to claim 3, wherein the second layer contains at least Cu—Ta—S.

5. The semiconductor device according to claim 4, wherein X and Y are: 80≧X≧40, and 5≦Y≦20 in the compositional ratio for Cu—Ta—S assumed as Cu_{X}Ta_{Y}S_{(100-X-Y)}.

6. The semiconductor device according to claim 1, wherein the first layer contains at least Cu—Ta—O.

7. The semiconductor device according to claim 6, wherein X and Y are: 10≦X≦50, and 10≦Y≦30 in the compositional ratio for Cu—Ta—O assumed as Cu_{X}Ta_{Y}O_{(100-X-Y)}.

8. The semiconductor device according to claim 1, wherein the diameter of metal particles or metal compound particles observed in the first layer is 5 nm or less.

9. The semiconductor device according to claim 1, wherein the first layer has a perovskite structure or a structure which is distorted from positions for atom deciding the perovskite structure within a range of 10%.

10. A semiconductor device having a plurality of memory cells each comprising an information memory area and a selection device disposed at each intersection between a plurality of word lines and a plurality of bit lines crossing the word lines by way of an insulation layer,
wherein the information memory area has the semiconductor device according to claim 1, and
wherein information writing or information reading is performed by the application of a pulse voltage to the information memory area.

11. A method of manufacturing a semiconductor device comprising:
forming a lower electrode above a substrate;
forming a first memory layer containing at least one element selected from the group consisting of Ag, Cu, Au, and Zn, at least one element selected from the group consisting of Ta, W, Mo, and Gd, and oxygen above the lower electrode, further forming a second memory layer containing at least one element selected from the group consisting of Ag, Cu, Au, and Zn, at least one element selected from the group consisting of S, Se, and Te, thereby forming a memory layer containing at least two layers of the first memory layer and the second memory layer; and
forming an upper electrode above the recording layer,
wherein annealing is performed after forming the first memory layer, and the second memory layer is formed after the annealing.

12. The semiconductor manufacturing method according to claim 11, wherein the phase state of the first memory layer is changed from an amorphous to a crystalline state by annealing after forming the first memory layer.

13. The semiconductor manufacturing method according to claim 12, wherein the first memory layer contains Cu—Ta—O and the temperature of the annealing is 600° C. or higher.

14. The semiconductor manufacturing method according to claim 11, further comprising:
forming an interlayer dielectric film by using a Low-k material above the substrate,
wherein the substrate temperature upon annealing is 400° C. or lower.

15. The semiconductor manufacturing method according to claim 11, wherein the film deposition for the first memory layer is performed while heating the substrate.

16. The semiconductor manufacturing method according to claim 15, wherein the heating temperature for the substrate is 500° C. or higher.

17. The semiconductor manufacturing method according to claim 12, wherein annealing using laser is performed after film deposition of the first memory layer and then film deposition for the second memory layer is performed.

18. The semiconductor manufacturing method according to claim 17, which includes
a step of forming an interlayer dielectric film by using a Low-k material above the substrate and in which
the substrate temperature upon annealing is 400° C. or lower.

19. The semiconductor manufacturing method according to claim 11, wherein the lower electrode contains a composition including at least one member selected from the group consisting of W, Ti, TiN, TiAlN, TiW, TiSiC, TaN, and carbon cluster.

20. A method of manufacturing a semiconductor device comprising:
forming a lower electrode above a substrate;
forming a first memory layer containing at least one element selected from the group consisting of Ag, Cu, Au and Zn, and at least one element selected from the group consisting of S, Se, and Te above the lower electrode and, further, forming a second memory layer including a crystalline phase containing at least one element selected from the group consisting of Ag, Cu, Au and Zn, at least one element selected from the group consisting of Ta, W, Mo, and Gd, and oxygen over the first memory layer, thereby forming a memory layer containing at least two layers of the first memory layer and the second memory layer; and
forming an upper electrode above the recording layer.
